(19) United States
(12) Patent Application Publication
(10) Pub. No.: US 2024/0395780 A1
(43) Pub. Date: Nov. 28, 2024

(54) DISPLAY PANEL, MANUFACTURING METHOD THEREFOR, AND DISPLAY DEVICE

(71) Applicant: Tianma Advanced Display Technology Institute (Xiamen) Co., Ltd., Xiamen (CN)

(72) Inventors: Jingtao GUO, Xiamen (CN); Canyuan ZHANG, Xiamen (CN); Qiang GU, Xiamen (CN); Bo ZHOU, Xiamen (CN)

(73) Assignee: Tianma Advanced Display Technology Institute (Xiamen) Co., Ltd., Xiamen (CN)

(21) Appl. No.: 18/796,897

(22) Filed: Aug. 7, 2024

(30) Foreign Application Priority Data
Dec. 27, 2023 (CN) 202311830695.1

(51) Int. Cl. H01L 25/075; H01L 33/58; H01L 33/62

(52) U.S. Cl. CPC H01L 25/0753; H01L 33/58; H01L 33/62; H01L 2933/0058; H01L 2933/0066

(57) ABSTRACT

Provided display panel includes a first substrate and a light-emitting element array. The first substrate includes a supporting substrate, a light-shielding layer disposed on the supporting substrate and provided with multiple light-shielding openings, and a eutectic layer disposed on the supporting substrate and provided with multiple eutectic material blocks corresponding to the multiple light-shielding openings respectively. In the direction perpendicular to the first substrate, a eutectic material block overlaps a corresponding light-shielding opening. The light-emitting element array includes multiple light-emitting elements, and is electrically connected to the first substrate.

### CROSS-REFERENCE TO RELATED APPLICATION(S)

This application claims priority to Chinese Patent Application No. 202311830695.1 filed Dec. 27, 2023, the disclosure of which is incorporated herein by reference in its entirety.

### TECHNICAL FIELD

The present disclosure relates to the field of display technology, in particular, a display panel, a manufacturing method of a display panel, and a display device.

### BACKGROUND

A micro light-emitting diode (micro-LED) is a miniaturized LED. The chip size of a micro-LED is on the order of microns, which may be less than 100 microns. Micro-LED display panels are formed by micro-LEDs. Micro-LED display panels have the characteristics of, for example, high efficiency, high brightness, high reliability, and self-luminescence.

Based on the development needs of thinness and integration, micro-LED display panels have a high pixel density per unit area, which causes crosstalk caused by light reflection, and affects the display effect of the micro-LED display panels.

### SUMMARY

The invention provides a display panel, a manufacturing method of a display panel, and a display device to improve the display effect.

According to an aspect of the present disclosure, a display panel is provided and includes a first substrate and a light-emitting element array. The first substrate includes a supporting substrate, a light-shielding layer disposed on the supporting substrate, and a eutectic layer disposed on the supporting substrate. The light-shielding layer has multiple light-shielding openings. The eutectic layer includes multiple eutectic material blocks corresponding to the multiple light-shielding openings, respectively. In the direction perpendicular to the first substrate, a eutectic material block overlaps a corresponding light-shielding opening. The light-emitting element array includes multiple light-emitting elements, and the light-emitting element array is electrically connected to the first substrate.

According to another aspect of the present disclosure, a method for manufacturing a display panel is provided. The method is applied to the display panel as described above and includes: a first substrate and a light-emitting element array are provided, where the first substrate includes a supporting substrate; a light-shielding layer and a eutectic layer are formed on the supporting substrate, where the light-shielding layer has multiple light-shielding openings, the eutectic layer includes multiple eutectic material blocks corresponding to the multiple light-shielding openings, respectively, and in the direction perpendicular to the first substrate, a eutectic material block overlaps a corresponding light-shielding opening; and the light-emitting element array and the first substrate are laser bonded.

According to another aspect of the present disclosure, a display device is provided and includes a preceding display panel which includes a first substrate and a light-emitting element array. The first substrate includes a supporting substrate, a light-shielding layer disposed on the supporting substrate, and a eutectic layer disposed on the supporting substrate. The light-shielding layer has multiple light-shielding openings. The eutectic layer includes multiple eutectic material blocks corresponding to the multiple light-shielding openings, respectively. In the direction perpendicular to the first substrate, a eutectic material block overlaps a corresponding light-shielding opening. The light-emitting element array includes multiple light-emitting elements, and the light-emitting element array is electrically connected to the first substrate.

### BRIEF DESCRIPTION OF DRAWINGS

FIG. 1 is a schematic diagram of a display panel according to an embodiment of the present disclosure.

FIG. 2 is a sectional view taken along A11-A12 of the display panel in FIG. 1.

FIG. 3 is a schematic diagram of a light-shielding layer according to an embodiment of the present disclosure.

FIG. 4 is a top view illustrating the relationship between a light-shielding layer and a eutectic layer according to an embodiment of the present disclosure.

FIG. 5 is a sectional view taken along A21-A22 of the relationship between the light-shielding layer and the eutectic layer in FIG. 4.

FIG. 6 is a top view illustrating another relationship between a light-shielding layer and a eutectic layer according to an embodiment of the present disclosure.

FIG. 7 is a sectional view taken along A31-A32 of the relationship between the light-shielding layer and the eutectic layer in FIG. 6.

FIG. 8 is a top view illustrating another relationship between a light-shielding layer and a eutectic layer according to an embodiment of the present disclosure.

FIG. 9 is a sectional view taken along A41-A42 of the relationship between the light-shielding layer and the eutectic layer in FIG. 8.

FIG. 10 is a top view illustrating another relationship between a light-shielding layer and a eutectic layer according to an embodiment of the present disclosure.

FIG. 11 is another schematic diagram of a display panel according to an embodiment of the present disclosure.

FIG. 12 is a diagram illustrating the heating reaction between a light-shielding layer and a eutectic layer according to an embodiment of the present disclosure.

FIG. 13 is another schematic diagram of a display panel according to an embodiment of the present disclosure.

FIG. 14 is another schematic diagram of a display panel according to an embodiment of the present disclosure.

FIG. 15 is another schematic diagram of a light-shielding layer according to an embodiment of the present disclosure.

FIG. 16 is an enlarged schematic view of a BB1 region of the sectional view of the display panel FIG. 2.

FIG. 17 is a top view illustrating another relationship between a light-shielding layer and a eutectic layer according to an embodiment of the present disclosure.

FIG. 18 is a flowchart illustrating a method for manufacturing a display panel according to an embodiment of the present disclosure.

FIG. 19 is a flowchart illustrating the manufacturing of a first substrate according to an embodiment of the present disclosure.

FIG. 20 is another flowchart illustrating the manufacturing of a first substrate according to an embodiment of the present disclosure.

FIG. 21 is a flowchart illustrating laser bonding according to an embodiment of the present disclosure.

FIG. 22 is a schematic diagram illustrating laser bonding according to an embodiment of the present disclosure.

FIG. 23 is another flowchart illustrating the laser bonding according to an embodiment of the present disclosure.

FIG. 24 is a schematic diagram of a display device according to an embodiment of the present disclosure.

### DETAILED DESCRIPTION

It is to be noted that terms such as “first” and “second” in the description, claims, and drawings of the present disclosure are used to distinguish between similar objects and are not necessarily used to describe a particular order or sequence. It should be understood that the data used in this manner are interchangeable where appropriate so that the embodiments of the present disclosure described herein may also be implemented in a sequence not illustrated or described herein. Additionally, terms “comprising”, “including”, and any other variations thereof are intended to encompass a non-exclusive inclusion. For example, a process, method, system, product, or device that includes a series of steps or units not only includes the expressly listed steps or units but may also include other steps or units that are not expressly listed or are inherent to such a process, method, product, or device.

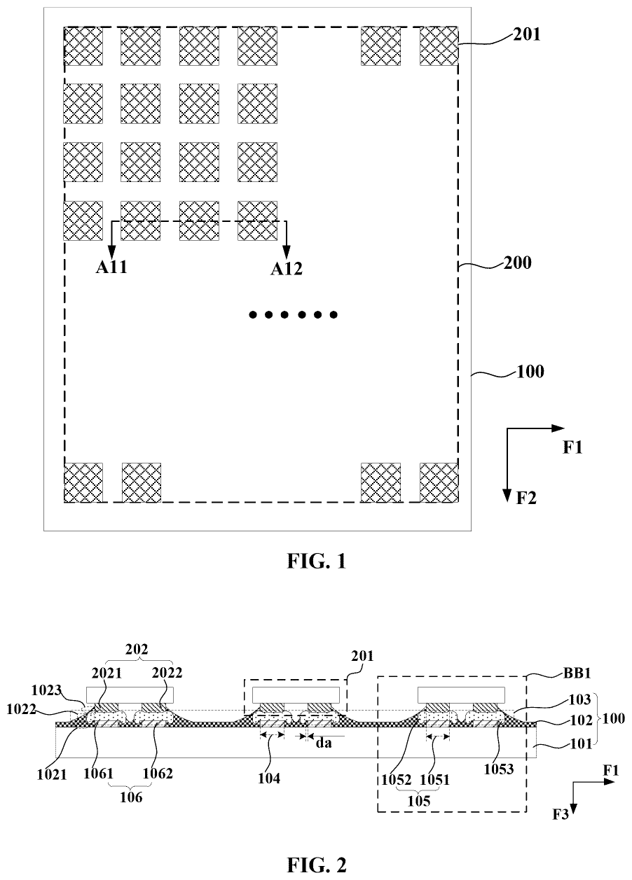

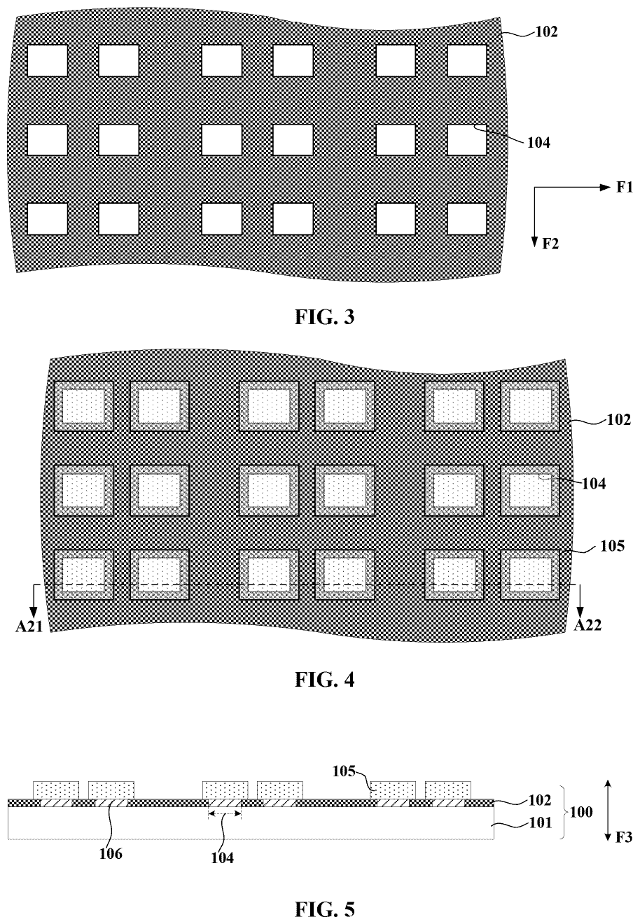

FIG. 1 is a schematic diagram of a display panel according to an embodiment of the present disclosure. FIG. 2 is a sectional view taken along A11-A12 of the display panel in FIG. 1. FIG. 3 is a schematic diagram of a light-shielding layer according to an embodiment of the present disclosure. This embodiment is applicable to the packaging of a display panel. As shown in FIG. 1 to FIG. 3, the display panel includes a first substrate 100 and a light-emitting element array 200; the first substrate 100 includes a supporting substrate 101, a light-shielding layer 102 disposed on the supporting substrate 101, and a eutectic layer 103 disposed on the supporting substrate 101; the light-shielding layer 102 has multiple light-shielding openings 104, the eutectic layer 103 includes multiple eutectic material blocks 105 corresponding to the multiple light-shielding openings 104, respectively, and in the direction perpendicular to the first substrate 100, a eutectic material block 105 overlaps a corresponding light-shielding opening 104; the light-emitting element array 200 includes multiple light-emitting elements 201, and the light-emitting element array 200 is electrically connected to the first substrate 100.

In this embodiment, the display panel includes a first substrate 100 and a light-emitting element array 200. The light-emitting element array 200 includes multiple light-emitting elements 201 and is electrically connected to the first substrate 100. In one or more embodiments, light-emitting elements 201 in the light-emitting element array 200 are electrically connected to the first substrate 100, when the first substrate 100 works, the light-emitting elements 201 in the light-emitting element array 200 is driven to emit light, and the display panel performs displaying. In one or more embodiments, a light-emitting element 201 is a micro light-emitting diode, and the display panel is a micro light-emitting diode display panel.

The first substrate 100 includes a supporting substrate 101, a light-shielding layer 102 disposed on the supporting substrate 101, and a eutectic layer 103 disposed on the supporting substrate 101. The supporting substrate 101 may be an array substrate that is configured to drive the light-emitting elements 201 in the light-emitting element array 200 to emit light. A light-shielding layer 102 is disposed on the supporting substrate 101. The patterned light-shielding layer 102 has multiple light-shielding openings 104. In one or more embodiments, the light-shielding layer 102 may be formed by a light-shielding material, and the light-shielding material at the light-shielding openings 104 in the light-shielding layer 102 is removed. A eutectic layer 103 is disposed on the supporting substrate 101. The eutectic layer 103 is formed by multiple eutectic material blocks 105. A gap exists between two adjacent eutectic material blocks 105. The eutectic layer 103 may be made of a metal material or an alloy material.

The light-emitting element array 200 is electrically connected to the first substrate 100 through the eutectic material blocks 105. A light-emitting element 201 includes a light-emitting electrode unit 202. The first substrate 100 includes a driving electrode unit 106. The light-emitting electrode unit 202 includes two light-emitting electrodes. The driving electrode unit 106 includes two driving electrodes. A eutectic material block 105 is disposed on the driving electrode unit 106. The process of manufacturing the display panel is briefly described as follows: A first substrate 100 and a light-emitting element array 200 are separately fabricated. The light-emitting element array 200 is transferred to the first substrate 100 so that the light-emitting electrode unit 202 of a light-emitting element 201 is attached to a eutectic material block 105. Then laser bonding is performed so that the eutectic material block 105 is melted and softened, and the light-emitting electrode unit 202, the eutectic material block 105, and a driving electrode unit 106 are bonded. After cooling, the eutectic material block 105 is cured, and the light-emitting element array 200 is bonded to the first substrate 100, where the light-emitting element 201 is electrically connected to the driving electrode unit 106. The laser may be an infrared laser.

For the first substrate 100, one eutectic material block 105 corresponds to one light-shielding opening 104. In one or more embodiments, in the third direction F3 perpendicular to the first substrate 100, the eutectic material block 105 overlaps a corresponding light-shielding opening 104. A first direction F1 and a second direction F2 intersects, and may be parallel to the light emission surface of the display panel. The third direction F3 is perpendicular to the first direction F1 and the second direction F2 and is defined as a direction perpendicular to the first substrate 100. It can be understood that the first substrate 100 and the light-emitting element array 200 are separately fabricated, and after being fabricated, the two are laser bonded to achieve an electrical connection. For the first substrate 100, in the third direction F3, the overlapping relationship of the eutectic material block 105 and the corresponding light-shielding opening 104 may be as follows: The light-shielding opening 104 partially exposes the eutectic material block 105 or completely exposes the eutectic material block 105.

FIG. 4 is a top view illustrating the relationship between a light-shielding layer and a eutectic layer according to an embodiment of the present disclosure. FIG. 5 is a sectional view taken along A21-A22 of the relationship between the light-shielding layer and the eutectic layer in FIG. 4. As shown in FIG. 4 and FIG. 5, in the third direction F3, the eutectic material block 105 covers a corresponding light-shielding opening 104. In one or more embodiments, the projection of the light-shielding opening 104 on the supporting substrate 101 is located inside the projection of the corresponding eutectic material block 105 on the supporting substrate 101.

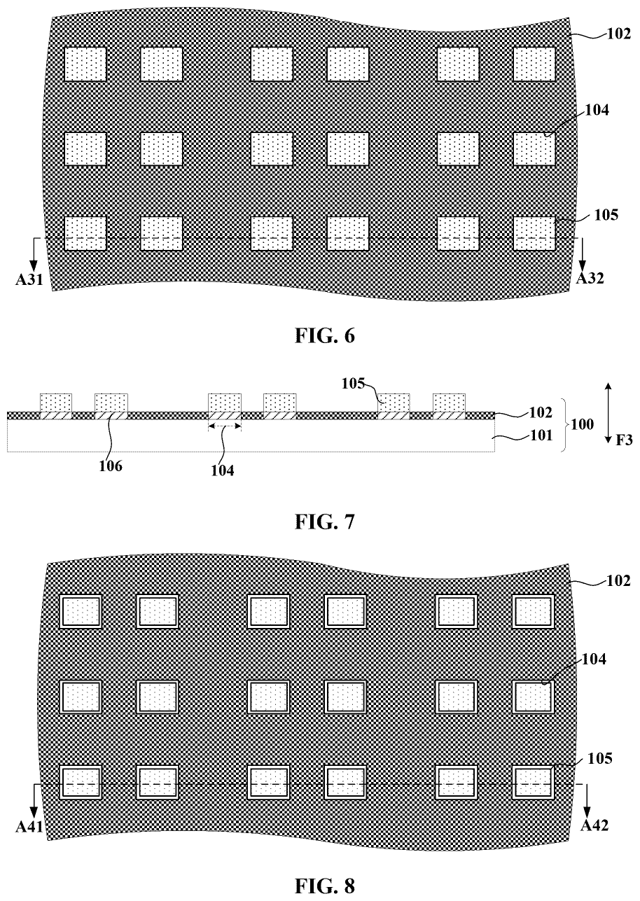

FIG. 6 is a top view illustrating another relationship between a light-shielding layer and a eutectic layer according to an embodiment of the present disclosure. FIG. 7 is a sectional view taken along A31-A32 of the relationship between the light-shielding layer and the eutectic layer in FIG. 6. As shown in FIG. 6 and FIG. 7, in the third direction F3, the eutectic material block 105 coincides with a corresponding light-shielding opening 104. In one or more embodiments, the projection of the eutectic material block 105 on the supporting substrate 101 coincides with that of the corresponding light-shielding opening 104 on the supporting substrate 101. The light-shielding opening 104 exposes the entire eutectic material block 105.

FIG. 8 is a top view illustrating another relationship between a light-shielding layer and a eutectic layer according to an embodiment of the present disclosure. FIG. 9 is a sectional view taken along A41-A42 of the relationship between the light-shielding layer and the eutectic layer in FIG. 8. As shown in FIG. 8 and FIG. 9, in the third direction F3, the light-shielding opening 104 covers a corresponding eutectic material block 105. In one or more embodiments, the projection of the eutectic material block 105 on the supporting substrate 101 is located inside the projection of the corresponding light-shielding opening 104 on the supporting substrate 101. The light-shielding opening 104 exposes the entire eutectic material block 105.

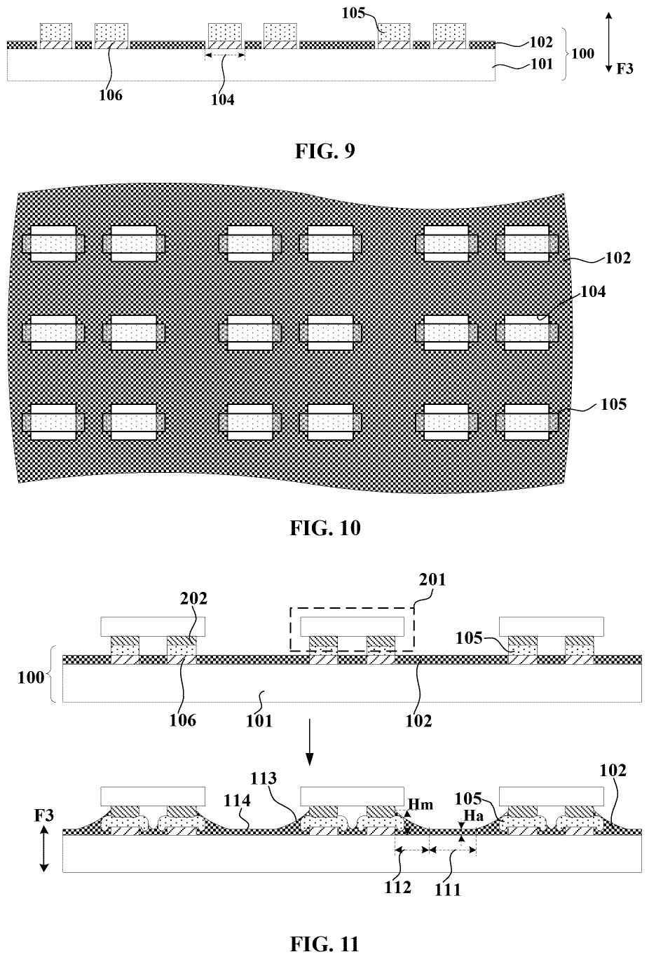

FIG. 10 is a top view illustrating another relationship between a light-shielding layer and a eutectic layer according to an embodiment of the present disclosure. As shown in FIG. 10, in the third direction F3, the light-shielding opening 104 partially overlaps with the corresponding eutectic material block 105. In one or more embodiments, the projection of the eutectic material block 105 on the supporting substrate 101 and the projection of the corresponding light-shielding opening 104 on the supporting substrate 101 have an overlapping part and non-overlapping parts. The light-shielding opening 104 exposes a portion of the eutectic material block 105

It should be noted that the overlapping relationship in the third direction F3 between the light-shielding opening in the light-shielding layer and the eutectic layer may be any one of the above illustrations or may be a combination of two or more of the above illustrations. For example, for a display panel, in the third direction F3, a situation exists where a eutectic material block coincides with a corresponding light-shielding opening, and a situation also exists where a light-shielding opening partially overlaps with a corresponding eutectic material block.

The light-shielding layer 102 includes a light-shielding material that can absorb light. The light-shielding layer 102 is disposed on the supporting substrate 101. The first substrate 100 and the light-emitting element array 200 are bonded and electrically connected using laser bonding. During the process of laser bonding, the light-shielding layer 102 can absorb the laser and reduce the laser power.

In one or more embodiments, in the case where a light-shielding layer is not provided in the display panel, during the process of laser bonding, the laser irradiates light-emitting elements and may also irradiate the first substrate between adjacent light-emitting elements, resulting in laser heat loss. Therefore, higher laser power is required to enable the first substrate to reach the temperature required for laser bonding. The reason for laser heat loss is as follows. The first substrate is placed on a stage during laser bonding, and the supporting substrate of the first substrate is mostly a glass substrate, and if the laser irradiates the first substrate between light-emitting elements, the laser will be projected through the first substrate to the stage; however, the stage has good thermal conductivity, causing laser heat loss.

However, in this embodiment, a light-shielding layer 102 is disposed in the display panel. During the process of laser bonding, the laser irradiated between adjacent light-emitting elements 201 is absorbed by the light-shielding layer 102. After absorbing the laser energy, the light-shielding layer 102 can heat and insulate the first substrate 100 and reduce laser heat loss. Compared with the case where a light-shielding layer is not provided, the light-shielding layer 102 enables the first substrate 100 to reach the temperature required for bonding with lower laser power, reduce the laser power, and improve the bonding yield.

The light-shielding layer 102 includes a light-shielding material that can absorb light and reduce light reflectivity. In one or more embodiments, in the third direction F3, the eutectic material block 105 at least partially overlaps a corresponding light-shielding opening 104, and a light-shielding layer 102 is disposed between corresponding adjacent driving electrodes. When the external light enters the display panel, the light-shielding layer 102 can absorb the external light, reduce the reflectivity of the external light, reduce the light-emitting crosstalk of the external light to the light-emitting element 201, and improve the display effect. In addition, part of the light emitted by the light-emitting element 201 may be projected to the supporting substrate 101. The light-shielding layer 102 can absorb the light, reduce the reflectivity of the supporting substrate 101 to the light emitted by the light-emitting element 201, reduce light-emitting crosstalk, and improve the display effect.

The light-shielding layer 102 is formed on the supporting substrate 101. In the third direction F3, the eutectic material block 105 at least partially overlaps the corresponding light-shielding opening 104. Therefore, the light-shielding layer 102 can play an insulating role, preventing short circuits between the light-emitting element 201 and the supporting substrate 101, between the driving electrodes, and between the eutectic material block 105 and the supporting substrate 101.

It should be noted that during the process of laser bonding, the eutectic material block 105 is melted and softened to bond the light-emitting element 201 and the first substrate 100, and in the bonding process, the eutectic material block 105 is pressed and deformed.

In one or more embodiments, the light-shielding layer material includes at least carbon powder and adhesive. The adhesive may be epoxy resin.

In the present disclosure, the display panel includes a light-shielding layer disposed on the supporting substrate, the light-shielding layer has multiple light-shielding openings, and the eutectic layer includes multiple eutectic material blocks corresponding to the multiple light-shielding openings, respectively; in the direction perpendicular to the first substrate, a eutectic material block at least partially overlaps a corresponding light-shielding opening. In the present disclosure, the light-shielding layer is formed on the supporting substrate. During the process of laser bonding, the light-shielding layer can absorb the laser to heat the first substrate, preserve the heat, and reduce the laser heat loss. Moreover, the light-shielding layer enables the first substrate to reach the temperature required for bonding with lower laser power, reduce the laser power, and improve the bonding yield. In addition, the light-shielding layer can absorb external light entering the display panel and the light projected by a light-emitting element to the substrate, reduce the light reflectivity, weaken the light-emitting crosstalk, and improve the display effect.

In one or more embodiments, the light-shielding layer includes a thermoplastic light-shielding material. The characteristics of a thermoplastic material are as follows: The thermoplastic material is melted when the temperature is above its melting point and solidifies when cooled.

In this embodiment, the light-shielding material of the light-shielding layer is a thermoplastic light-shielding material, and when the temperature of the light-shielding layer is higher than or equal to the melting point of the thermoplastic light-shielding material, the light-shielding layer is melted and becomes fluid, and the light-shielding layer may flow on the supporting substrate, which facilitates the overlapping of the light-shielding layer and a eutectic material block. When the temperature of the light-shielding layer is lower than the melting point of the thermoplastic light-shielding material, the light-shielding layer solidifies into a solid state when cooled, ensuring the normal operation of the display panel. It should be noted that the melting and flow of the light-shielding layer is similar to a capillary phenomenon, and the flow can fill in the gaps. When an obstacle is encountered, the flow automatically extends upward along the obstacle.

FIG. 11 is another schematic diagram of a display panel according to an embodiment of the present disclosure. As shown in FIG. 11, during the process of laser bonding, laser power is controlled to provide the temperature required for bonding. The bonding temperature is higher than or equal to the melting point of the eutectic material block 105 so that the eutectic material block 105 is melted. After cooling, the eutectic material block 105 is solidified so that the light-emitting element 201 is bonded to the first substrate 100. In this process of laser bonding, the light-shielding layer 102 absorbs the laser energy. When the temperature of the light-shielding layer 102 is higher than or equal to the melting point of the thermoplastic light-shielding material, the light-shielding layer 102 is melted and becomes fluid, and the light-shielding layer 102 may flow on the supporting substrate 101. The fluid light-shielding layer 102 may fill the gap between driving electrodes and may also flow to contact the eutectic material block 105 and extend upward along the sidewall of the eutectic material block 105, thereby facilitating the overlapping of the light-shielding layer 102 and the eutectic material block 105 in the third direction F3. The light-shielding layer 102 contacts the eutectic material block 105, and the light-shielding material may absorb light. In this case, part of the light projected to the eutectic material block 105 can be absorbed by the light-shielding layer 102 so that the light reflectivity of the eutectic material block 105 is reduced, light-emitting crosstalk is reduced, and the display effect is improved.

In one or more embodiments, the light-emitting element array is bonded and electrically connected to the first substrate, and the temperature at which the light-emitting element array and the first substrate are bonded is higher than or equal to the melting point of the light-shielding material. In this embodiment, during the process of laser bonding, laser power is controlled to provide the temperature required for bonding so that the light-emitting element array is bonded and electrically connected to the first substrate. The temperature for laser bonding may be higher than or equal to the melting point of the light-shielding material, which can cause the light-shielding layer to melt and become a fluid liquid. Thus, the light-shielding layer is facilitated to flow to contact the eutectic material block, thereby reducing the light reflectivity of the eutectic material block.

In one or more embodiments, the melting point of the light-shielding material is higher than or equal to the melting point of the eutectic material block. In this embodiment, the melting point of the light-shielding material of the light-shielding layer may be higher than or equal to the melting point of the eutectic material block. During the process of laser bonding, laser power is controlled to provide the temperature required for bonding. The temperature for laser bonding may be designed to be higher than or equal to the melting point of the light-shielding material. In this case, the eutectic material block can melt, which facilitates the bonding and electrical connection between the light-emitting element array and the first substrate. Moreover, the light-shielding layer can melt and become a fluid liquid. Thus, the light-shielding layer is facilitated to flow to contact the eutectic material block, reducing the light reflectivity of the eutectic material block.

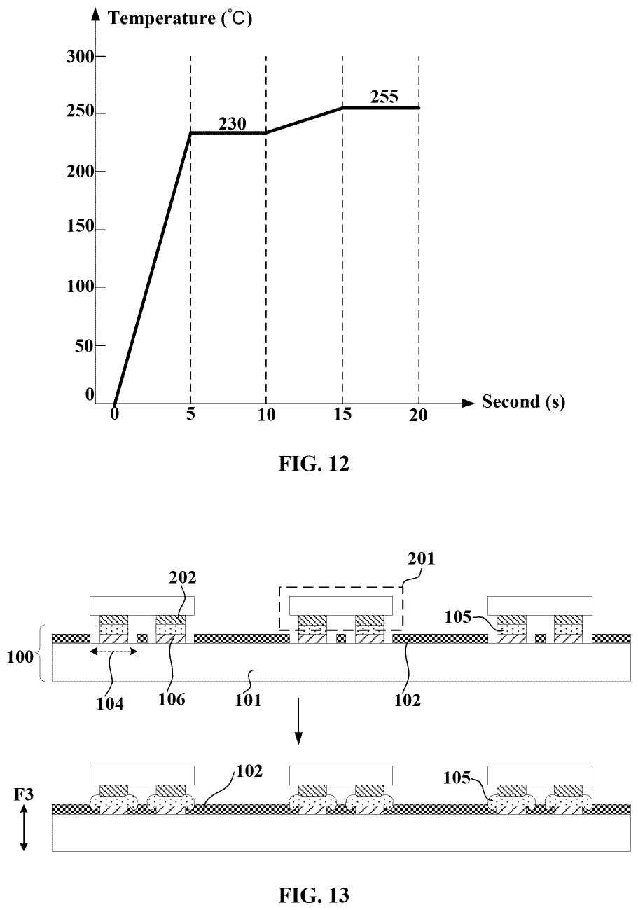

FIG. 12 is a diagram illustrating the heating reaction between a light-shielding layer and a eutectic layer according to an embodiment of the present disclosure. As shown in FIG. 12, the melting point of the eutectic material block is greater than 200° C. and less than 250° C., and the melting point of the light-shielding layer is greater than or equal to 250° C. Illustratively, the melting point of the eutectic material block is 230° C., and the melting point of the light-shielding layer is 255° C. During the process of laser bonding, laser power may be controlled to provide the temperature required for bonding. In one or more embodiments, the temperature for laser bonding may be directly controlled to be 260° C. Then, when the temperature rises to 230° C., the eutectic material block starts to melt, and when the temperature rises to 255° C., the light-shielding layer starts to melt. In one or more embodiments, the duration of bonding the eutectic material block is greater than or equal to 5 seconds, and the duration of melting the light-shielding layer is greater than or equal to 5 seconds, which helps ensure the melting of the eutectic material block and the flow of the light-shielding layer with a higher melting point. Moreover, the short circuit is prevented. Based on this, in one or more embodiments, the duration of laser bonding is 25 seconds, which can ensure the flow of the light-shielding layer with a higher melting point and help prevent the short circuit.

In one or more embodiments, the light-shielding layer is in contact with a side surface of the eutectic material block. As shown in FIG. 2, the light-shielding layer 102 is in contact with a side surface of the eutectic material block 105, and the light-shielding material may absorb light. In this case, the light projected to the side surface of the eutectic material block 105 can be absorbed by the light-shielding layer 102 so that the light reflectivity of the eutectic material block 105 is reduced, light-emitting crosstalk is reduced, and the display effect is improved. It can be understood that the melting and flow of the light-shielding layer 102 is similar to a capillary phenomenon, and the flow may fill between driving electrodes and extend upward along the sidewall of the eutectic material block 105 when contacting the eutectic material block 105.

It should be noted that by the control of the thickness of the light-shielding layer and/or the size of the light-shielding opening, the overlapping relationship of the light-shielding layer and the eutectic material block in the direction perpendicular to the first substrate can be adjusted. In one or more embodiments, when the light-shielding layer is formed, the thickness of the light-shielding layer may be reasonably controlled so that after the light-shielding layer flows, coating on the gap between the driving electrodes, the sides of the driving electrodes, and the sidewall of the eutectic material block is achieved.

FIG. 13 is another schematic diagram of a display panel according to an embodiment of the present disclosure. As shown in FIG. 13, the light-shielding opening 104 is larger, and in the third direction F3, the projection of the eutectic material block 105 on the supporting substrate 101 is located inside the projection of the light-shielding opening 104 on the supporting substrate 101. During the process of laser bonding, after the light-shielding layer 102 is melted and becomes fluid, the fluid light-shielding layer 102 may only be used to fill the gap between the driving electrodes and cannot extend to the sidewall of the eutectic material block 105. It can be understood that if the size of the light-shielding opening 104 is reduced and/or the thickness of the light-shielding layer 102 in the third direction F3 is increased, the light-shielding layer 102 during the process of laser bonding may flow to contact the eutectic material block 105 and may even flow upward along the sidewall of the eutectic material block 105.

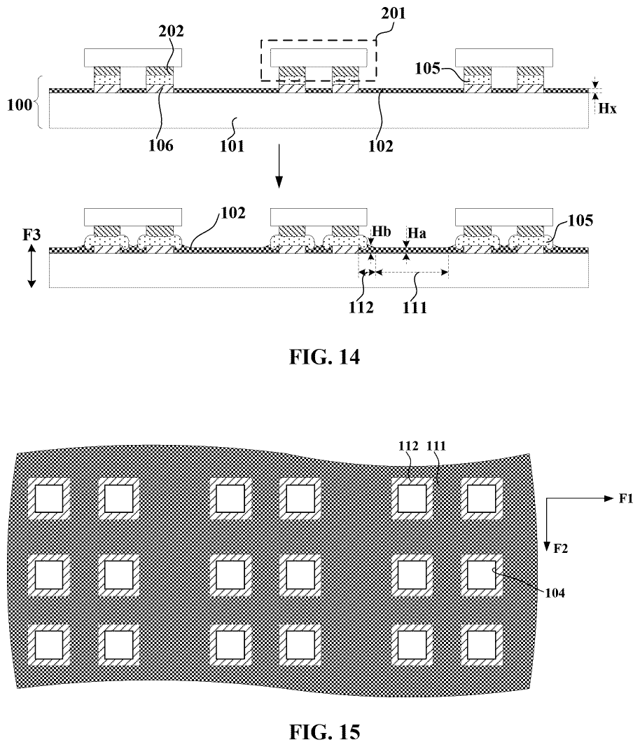

FIG. 14 is another schematic diagram of a display panel according to an embodiment of the present disclosure. As shown in FIG. 14, in the third direction F3, the thickness of light-shielding layer 102 is Hx. The thickness Hx is relatively small. In one or more embodiments, a distance exists between the side surface of the light-shielding layer 102 away from the supporting substrate 101 and the eutectic material block 105. During the process of laser bonding, after the light-shielding layer 102 is melted and becomes fluid, the fluid light-shielding layer 102 may only be used to fill the gap between the driving electrodes or may only extend to cover part of the sidewall of the eutectic material block 105.

It can be understood that by the control of the thickness of the light-shielding layer 102 and/or the size of the light-shielding opening 104, the light-shielding layer 102 can contact the eutectic material block 105 after melting and flowing during the process of laser bonding, and the light-shielding layer 102 is in contact with the sidewall of the eutectic material block 105. In this case, the light projected to the sidewall of the eutectic material block 105 can be absorbed by the light-shielding layer 102 so that the light reflectivity of the eutectic material block 105 is reduced, light-emitting crosstalk is reduced, and the display effect is improved.

In one or more embodiments, the light-shielding layer disposed between two adjacent eutectic material blocks includes a first block and a second block, and the first block is disposed on a side of the second block away from the two adjacent eutectic material blocks; Ha≤Hb; in the direction perpendicular to the first substrate, Ha denotes the thickness of the first block, and Hb denotes the thickness of the second block away from the two adjacent eutectic material blocks. It can be understood that the first block and the second block of the light-shielding layer are merely divided for simplifying description, and in practice, the light-shielding layer is unnecessary to be divided into a first block and second blocks.

FIG. 15 is another schematic diagram of a light-shielding layer according to an embodiment of the present disclosure. As shown in FIGS. 14 and 15, the light-shielding layer 102 disposed between two adjacent eutectic material blocks 105 may be divided into a first block 111 and a second block 112, and the first block 111 is disposed on a side of the second block 112 away from the two adjacent eutectic material blocks 105. In the third direction F3 perpendicular to the first substrate 100, the thickness of the first block 111 is Ha, and the thickness of the second block 112 facing to the two adjacent eutectic material blocks 105 is Hb. During the process of laser bonding, the light-shielding layer 102 is melted and flows, contacts the eutectic material block 105, and may extend upward along the sidewall of the eutectic material block 105. Therefore, the thickness of the first block 111 of the light-shielding layer 102 may not be uniform, and the thickness of the second block 112 may also be different. Ha and Hb satisfies the following: Ha≤Hb. Then the maximum thickness of the first block 111 away from the eutectic material block 105 is less than or equal to the minimum thickness of the second block 112 facing to the eutectic material block 105, which facilitates contact of the light-shielding layer 102 with the sidewall of the eutectic material block 105. Based on this, the light-shielding layer 102 may absorb the light projected to the eutectic material block 105, reduce the light reflectivity of the eutectic material block 105, reduce the light-emitting crosstalk, and improve the display effect.

In one or more embodiments, 2×Ha≤Hm; in the direction perpendicular to the first substrate, Hm is the thickness of a side of the second block facing to the two adjacent eutectic material blocks 105.

As shown in FIG. 11, during the process of laser bonding, the light-shielding layer 102 is melted and flows and contacts the eutectic material block 105. When the light-shielding layer 102 is melted and flows and extends upward along the sidewall of the eutectic material block 105, the thickness of the second block 112 of the light-shielding layer 102 varies. The thickness of a side of the second block 112 facing to the eutectic material block 105 is thicker, and the thickness of a side of the second block 112 facing to the first block 111 is thinner. In the third direction F3 perpendicular to the first substrate 100, the thickness of the side of the second block 112 facing to the eutectic material block 105 is Hm, and Ha and Hm satisfies the following: 2×Ha≤Hm. Therefore, the maximum thickness of the second block 112 is larger than or equal to twice the maximum thickness of the first block 111, which facilitates the contact between the light-shielding layer 102 and the sidewall of the eutectic material block 105. Based on this, the light-shielding layer 102 may absorb the light projected to the eutectic material block 105, reduce the light reflectivity of the eutectic material block 105, reduce the light-emitting crosstalk, and improve the display effect.

In one or more embodiments, a side of the second block away from the supporting substrate is an arc-shaped edge, and the arc-shaped edge is convex toward one of the two adjacent eutectic material blocks. In one or more embodiments, a side of the first block away from the supporting substrate is a straight edge.

In this embodiment, during the process of laser bonding, the light-shielding layer is melted and flows between adjacent eutectic material blocks so that the light-shielding layer contacts the eutectic material block and extends upward along the sidewall of the eutectic material block. Thus, the light reflectivity of the eutectic material block is reduced, and the display effect is improved. As shown in FIG. 11, based on the fluidity of the light-shielding layer 102, after the light-shielding layer 102 extends upward along the sidewall of the eutectic material block 105, a side of the second block 112 away from the supporting substrate 101 presents an arc-shaped edge 113, and the arc-shaped edge 113 is convex toward the eutectic material block 105. Based on the fluidity of the light-shielding layer 102, after the light-shielding layer 102 flows between adjacent eutectic material blocks 105, a side of the first block 111 away from the supporting substrate 101 presents a straight edge 114.

It can be understood that the melting and flow of the light-shielding layer 102 is similar to a capillary phenomenon. When the flow of the light-shielding layer 102 fills in the position where the first block is located, a side of the first block 111 away from the supporting substrate 101 appears as a nearly straight edge. When the light-shielding layer 102 extends upward along the sidewall of the eutectic material block 105, a side of the second block 112 away from the supporting substrate 101 presents an arc-shaped edge 113 based on the capillary phenomenon.

In some embodiments, in the direction perpendicular to the first substrate, the eutectic material block covers the corresponding light-shielding opening. As shown in FIG. 13, during the process of laser bonding, the light-shielding layer 102 is melted and flows, the eutectic material block 105 is melted to bond a light-emitting element 201 and a driving electrode unit 106, and the eutectic material block 105 during the process of laser bonding is pressed and deformed. In this way, in the third direction F3, the area of the pressed and deformed eutectic material block 105 increases and covers a corresponding light-shielding opening 104.

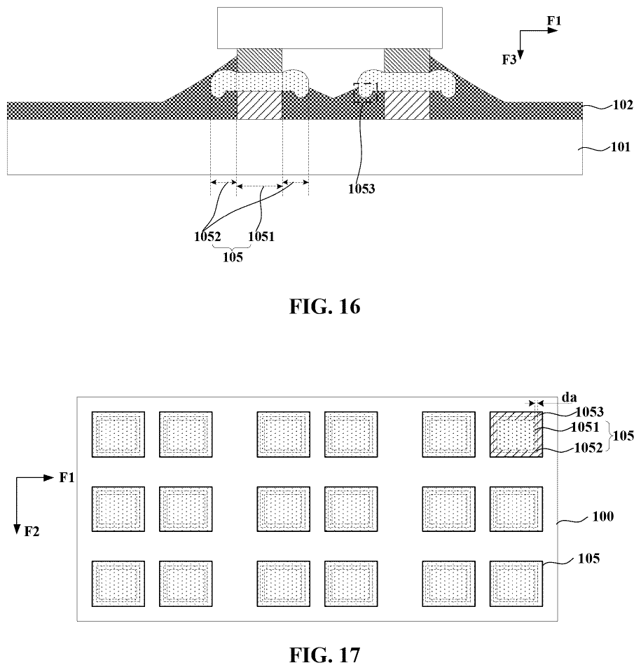

FIG. 16 is an enlarged schematic view of a BB1 region of the sectional view of the display panel FIG. 2. As shown in FIG. 2 and FIG. 16, in one or more embodiments, the supporting substrate 101 includes multiple driving electrode units 106, a driving electrode unit 106 includes a first driving electrode 1061 and a second driving electrode 1062, and a light-emitting element 201 includes a first light-emitting electrode 2021 and a second light-emitting electrode 2022. A light-emitting element 201 is electrically connected to a driving electrode unit 106. The first light-emitting electrode 2021 is bonded and electrically connected to the first driving electrode 1061 through one eutectic material block 105, and the second light-emitting electrode 2022 is bonded and electrically connected to the second driving electrode 1062 through another eutectic material block 105. The eutectic material block 105 includes a first bonding part 1051 and a second bonding part 1052, and in the third direction F3 perpendicular to the first substrate 100, the first bonding part 1051 overlaps one of the first light-emitting electrode and the second light-emitting electrode in the light-emitting element 201 or the first bonding part 1051 overlaps one of the first driving electrode and the second driving electrode in the driving electrode unit 106, and the second bonding part 1052 overlaps none of the first light-emitting electrode or the second light-emitting electrode in the light-emitting element 201 or the second bonding part 1052 overlaps none of the first driving electrode or the second driving electrode in the driving electrode unit 106.

During the process of laser bonding, the eutectic material block 105 is melted, and when bonding the light-emitting element 201 and the driving electrode unit 106, the eutectic material block 105 molten is pressed and deformed. The eutectic material block 105 solidified may be divided into a first bonding part 1051 and a second bonding part 1052. In the third direction F3, the first bonding part 1051 overlaps the light-emitting electrode in the light-emitting element 201 or the driving electrode in the driving electrode unit 106. In the third direction F3, the second bonding part 1052 does not overlap the light-emitting electrode in the light-emitting element 201 or the driving electrode in the driving electrode unit 106.

In this embodiment, for the eutectic material block 105 solidified, in the third direction F3, either the portion of the eutectic material that coincides with the light-emitting electrode or the portion of the eutectic material that coincides with the driving electrode may be defined as the first bonding part 1051, and the second bonding part 1052 is a portion of the eutectic material excluding the first bonding part 1051. With reference to FIG. 2 and FIG. 7, in the third direction F3, the eutectic material block prior to bonding, the driving electrode, and the light-emitting electrode are in contact and coincide. After the eutectic material block prior to bonding is pressed and deformed and is solidified, the first bonding part 1051 of the eutectic material block 105 solidified may be defined as a eutectic material portion coinciding with the eutectic material block prior to bonding, and the second bonding part 1052 is a eutectic material portion excluding the first bonding part 1051.

In one or more embodiments, the second bonding part 1052 has a protrusion 1053 facing to the supporting substrate 101. During the process of laser bonding, the molten eutectic material block 105 is pressed and deformed to form a second bonding part 1052. Based on this, the second bonding part 1052 of the eutectic material block 105 is provided with a protrusion 1053 facing to the supporting substrate 101. The protrusion 1053 is formed by the pressure and deformation and faces to the supporting substrate 101 under the action of gravity. After the eutectic material block 105 is solidified, the second bonding part 1052 has a protrusion 1053 facing to the supporting substrate 101.

In one or more embodiments, in the direction perpendicular to the first substrate, the protrusion surrounds the first bonding part. FIG. 17 is a top view illustrating another relationship between a light-shielding layer and a eutectic layer according to an embodiment of the present disclosure. The first substrate 100 is the first substrate structure after bonding, and the light-emitting element welded to the first substrate 100 is not shown. With reference to FIGS. 2 and 17, the eutectic material block 105 includes a first bonding part 1051 and a second bonding part 1052. In the third direction F3 perpendicular to the first substrate 100, the first bonding part 1051 overlaps a light-emitting electrode in the light-emitting element 201 or a driving electrode in the driving electrode unit 106, and the second bonding part 1052 does not overlap the light-emitting electrode in the light-emitting element 201 or the driving electrode in the driving electrode unit 106. The second bonding part 1052 surrounds the first bonding part 1051, and the second bonding part 1052 has a protrusion 1053 facing to the supporting substrate 101. In the direction perpendicular to the first substrate, the protrusion 1053 surrounds the first bonding part 1051.

In one or more embodiments, in the direction parallel to the first substrate, a gap exists between the protrusion and the first driving electrode or the second driving electrode in the driving electrode unit. As shown in FIG. 2 and FIG. 17, the eutectic material block 105 includes a first bonding part 1051 and a second bonding part 1052. In this embodiment, an example is used where in the third direction F3, the first bonding part 1051 coincides with the first driving electrode and the second driving electrode in the driving electrode unit 106. In this way, the dotted frame of the first bonding part 1051 shown in FIG. 17 may be regarded as the projection of the first driving electrode and the second driving electrode in the third direction F3. In the direction parallel to the first substrate 100, a gap da exists between the protrusion 1053 and the first driving electrode or the second driving electrode adjacent to the protrusion 1053.

For the eutectic material block 105, the second bonding part 1052 of the eutectic material block 105 solidified has a protrusion 1053 facing to the supporting substrate 101, which helps ensure that the light-emitting element 201 is fully bonded to the first substrate 100 through the eutectic material block 105.

As shown in FIG. 2, in one or more embodiments, the light-shielding layer 102 includes a first extension part 1021 and a second extension part 1022. The first extension part 1021 extends to a side of a eutectic material block 105 away from a light-emitting element 201 and is in contact with a side of a driving electrode in a driving electrode unit 106; and the second extension part 1022 extends along the side of the eutectic material block 105 and is in contact with the first extension part 1021.

In this embodiment, a light-shielding layer 102 is disposed in the display panel, and the light-shielding layer 102 fills the gap between driving electrodes, fills the gap between the eutectic material block 105 and the driving electrode, and partially covers the sidewall of the eutectic material block 105. Based on this, the light-shielding layer 102 can prevent the short circuit between adjacent driving electrodes, improve the reliability of the display panel, and reduce the light reflectivity of the driving electrodes. In addition, during the process of laser bonding, the laser irradiated between adjacent driving electrodes can be absorbed by the light-shielding layer 102, and after absorbing the laser energy, the light-shielding layer 102 can heat and insulate the first substrate 100, thereby reducing laser heat loss.

In one or more embodiments, the light-shielding material of the light-shielding layer 102 is a thermoplastic light-shielding material. When the temperature of the light-shielding layer 102 is higher than or equal to the melting point of the thermoplastic material, the light-shielding layer 102 may melt and become a fluidity liquid. When the temperature of the light-shielding layer 102 is lower than the melting point of the thermoplastic material, the light-shielding layer 102 can be cooled and solidified to a solid state to ensure the normal operation of the display panel.

As described above, during the process of laser bonding, the light-shielding layer 102 is melted and flows and fills the gap between the driving electrodes. The light-shielding layer 102 also is melted and flows to contact the eutectic material block 105 and extend along the sidewall of the eutectic material block 105. Correspondingly, the light-shielding layer 102 includes a first extension part 1021 and a second extension part 1022. It can be understood that the first extension part 1021 and the second extension part 1022 in FIG. 2 are only schematic diagrams that are used to represent a relative position between the first extension part 1021 and the second extension part 1022. The first extension part 1021 may extend to a side of the eutectic material block 105 away from the light-emitting element 201 and is in contact with a side of the driving electrode in the driving electrode unit 106 so that the light-shielding layer 102 can fill a gap between adjacent driving electrodes to prevent the driving electrodes from being short-circuited. The second extension part 1022 is in contact with the first extension part 1021 and extends along a side of the eutectic material block 105. The light-shielding layer 102 covers the side of the eutectic material block 105 and can absorb light and reduce the light reflectivity of the eutectic material block 105.

In one or more embodiments, the first extension part 1021 is filled in a gap between the eutectic material block 105 and the driving electrode in the driving electrode unit 106. For the eutectic material block 105, during the process of laser bonding, the eutectic material block 105 is pressed and deformed, and the second bonding part 1052 of the eutectic material block 105 has a protrusion 1053 facing to the supporting substrate 101. The light-shielding layer 102 is fluid, and the first extension part 1021 can be filled in the gap da between the eutectic material block 105 and the driving electrode in the driving electrode unit 106, which can prevent the driving electrode from being short-circuited. The first extension part 1021 is filled between the protrusion 1053 and the supporting substrate 101, which can prevent the short circuit between the eutectic material block 105 and the supporting substrate 101.

In one or more embodiments, the light-shielding layer 102 also includes a third extension part 1023; the third extension part 1023 extends to a side of a eutectic material block 105 away from a driving electrode unit 106, the third extension part 1023 is in contact with a side of a light-emitting electrode in a light-emitting element 201, and the third extension part 1023 is in contact with the second extension part 1022.

In this embodiment, a light-shielding layer 102 is disposed in the display panel, and the light-shielding layer 102 fills the gap between driving electrodes, fills the gap between the eutectic material block 105 and the driving electrode, and covers the sidewall of the eutectic material block 105. On this basis, the third extension part 1023 of the light-shielding layer 102 also extends to a side of the eutectic material block 105 away from the driving electrode unit 106. Based on this, the light-shielding layer 102 can prevent the short circuit between adjacent driving electrodes, improve the reliability of the display panel, and reduce the light reflectivity of the driving electrodes. Moreover, the light-shielding layer 102 covers at least the sidewall of the eutectic material block 105 and can reduce the light reflectivity of the eutectic material block 105.

In addition, during the process of laser bonding, the laser irradiated between adjacent driving electrodes can be absorbed by the light-shielding layer 102, and after absorbing the laser energy, the light-shielding layer 102 can heat and insulate the first substrate 100, thereby reducing laser heat loss.

The light-shielding material of the light-shielding layer 102 is a thermoplastic light-shielding material. When the temperature of the light-shielding layer 102 is higher than or equal to the melting point of the thermoplastic material, the light-shielding layer 102 may melt and become a fluidity liquid. When the temperature of the light-shielding layer 102 is lower than the melting point of the thermoplastic material, the light-shielding layer 102 can be cooled and solidified to a solid state to ensure the normal operation of the display panel.

As described above, during the process of laser bonding, the light-shielding layer 102 is melted and flows and fills the gap between the driving electrodes. The light-shielding layer 102 also is melted and flows to contact the eutectic material block 105 and extend along the sidewall of the eutectic material block 105. When the light-shielding layer 102 continues to flow, the light-shielding layer 102 may also completely cover the sidewall of the eutectic material block 105 and extend along a side of the eutectic material block 105 away from the supporting substrate 101. Correspondingly, the light-shielding layer 102 also includes a third extension part 1023. The third extension part 1023 is in contact with the second extension part 1022 and extends along a side of the eutectic material block 105 away from the supporting substrate 101 so that the light-shielding layer 102 covers the side of the eutectic material block 105 and at least partially covers a side of the eutectic material block 105 away from the supporting substrate 101.

The light-shielding layer 102 includes a first extension part 1021, a second extension part 1022, and a third extension part 1023. The first extension part 1021 fills a gap between adjacent driving electrodes, which can prevent the driving electrodes from being short-circuited. The first extension part 1021 also fills a gap between the protrusion 1053 and the supporting substrate 101, which can prevent the eutectic material block 105 from being short-circuited. The second extension part 1022 and the third extension part 1023 cover the sidewall of the eutectic material block 105 and partially cover a side of the eutectic material block 105 away from the supporting substrate 101, so as to absorb light, reduce the light reflection of the eutectic material block 105, and improve the display effect.

In one or more embodiments, the first extension part 1021, the second extension part 1022, and the third extension part 1023 of the light-shielding layer 102 are all in contact with the second bonding part 1052 of the eutectic material block 105. In this embodiment, the first extension part 1021 contacts the second bonding part 1052 and may fill a gap between the protrusion 1053 and the supporting substrate 101 to prevent the eutectic material block 105 from being short-circuited. The second extension part 1022 and the third extension part 1023 cover the sidewall of the eutectic material block 105 and partially cover a side of the eutectic material block 105 away from the supporting substrate 101, so as to absorb light, reduce the light reflectivity of the second bonding part 1052 of the eutectic material block 105, and improve the display effect.

In one or more embodiments, in the direction perpendicular to the first substrate, the light-shielding layer covers the second bonding part of a eutectic material block. As shown in FIG. 2, in the third direction F3, the light-shielding layer 102 covers the second bonding part 1052 of the eutectic material block 105, and the light projected to the second bonding part 1052 of the eutectic material block 105 can be completely absorbed by the light-shielding layer 102, reducing the light reflectivity of the second bonding part 1052 of the eutectic material block 105 and improving the display effect.

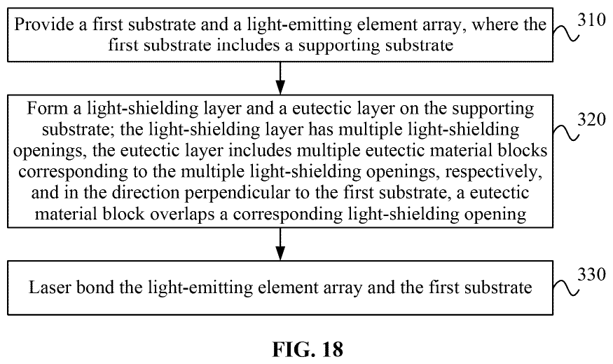

Based on the same inventive concept, the embodiments of the present disclosure also provide a method for manufacturing a display panel. The method is applied to manufacturing the display panel as described in any of the preceding embodiments. FIG. 18 is a flowchart illustrating a method for manufacturing a display panel according to an embodiment of the present disclosure. As shown in FIG. 18, the method includes the steps described below.

In S310, a first substrate and a light-emitting element array are provided, where the first substrate includes a supporting substrate.

In S320, a light-shielding layer and a eutectic layer are formed on the supporting substrate; the light-shielding layer has multiple light-shielding openings, the eutectic layer includes multiple eutectic material blocks corresponding to the multiple light-shielding openings, respectively, and in the direction perpendicular to the first substrate, a eutectic material block overlaps a corresponding light-shielding opening.

In S330, the light-emitting element array and the first substrate are laser bonded.

In this embodiment, the display panel may be a micro light-emitting diode display panel. In the process of manufacturing the micro light-emitting diode display panel, it is necessary to use the mass transfer technology to bond the light-emitting element array to the first substrate, where the first substrate includes a supporting substrate. Therefore, the first substrate and the light-emitting element array are manufactured independently of each other. In 310, the supporting substrate is an array substrate that has been completed, and the light-emitting element array may be understood as a to-be-transferred light-emitting element array on a source substrate.

For the supporting substrate, a light-shielding layer and a eutectic layer need to be formed on the supporting substrate; the light-shielding layer has multiple light-shielding openings, the eutectic layer includes multiple eutectic material blocks corresponding to the multiple light-shielding openings, respectively, and in the direction perpendicular to the supporting substrate, a eutectic material block overlaps a corresponding light-shielding opening.

The light-emitting element array is separated from the source substrate, the separated light-emitting element array is transferred and placed on the supporting substrate through a transfer apparatus, and the light-emitting element array is bonded and electrically connected to the first substrate using the laser bonding technology, where a light-emitting electrode of a light-emitting element is electrically connected to a driving electrode of the first substrate through a molten eutectic material block. After the eutectic material block is solidified, the light-emitting element array and the first substrate are bonded.

In the present disclosure, the light-shielding layer during the process of laser bonding can absorb the laser to heat the supporting substrate, preserve the heat, and reduce the laser heat loss. Moreover, the light-shielding layer can enable the supporting substrate to reach the temperature required for bonding as quickly as possible with lower laser power and reduce the laser power. In addition, the light-shielding layer can absorb external light entering the display panel and the light projected by a light-emitting element to the supporting substrate, reduce the light reflectivity, weaken the light-emitting crosstalk, and improve the display effect.

The preceding manufacturing method is the subject of this embodiment, and the method will be described in detail below with specific examples.

In one or more embodiments, the light-shielding layer includes a thermoplastic light-shielding material. The thermoplastic light-shielding material is melted when the temperature is greater than or equal to its melting point and solidifies when the temperature is less than its melting point. Based on this, when the temperature of the light-shielding layer is higher than or equal to the melting point of the thermoplastic light-shielding material, the light-shielding layer may melt and flow, which helps fill the gap of the driving electrodes and helps contact the eutectic material block. When the temperature of the light-shielding layer is lower than the melting point of the thermoplastic light-shielding material, the light-shielding layer is cooled and solidified.

The operation of laser bonding the light-emitting element array and the first substrate in the optional S330 includes controlling the laser bonding temperature to be higher than or equal to the melting point of the light-shielding layer so that the light-emitting element array is bonded and electrically connected to the first substrate and the light-shielding layer is melted and flows. In one or more embodiments, the melting point of the light-shielding layer here is the melting point of the thermoplastic light-shielding material.

In this embodiment, the laser bonding temperature may be controlled to be equal to the melting point of the light-shielding layer, or the laser bonding temperature may be controlled to be greater than the melting point of the light-shielding layer. Based on this, during the process of laser bonding, the light-shielding layer absorbs the laser energy and heats up, and the light-shielding layer may heat up to a temperature higher than or equal to the melting point of the light-shielding layer. In this manner, the light-shielding layer is melted and flows so that the light-shielding layer is facilitated to fill a gap in the driving electrodes and contact a eutectic material block.

In one or more embodiments, the operation of laser bonding the light-emitting element array and the first substrate in S330 includes controlling the laser bonding temperature to be higher than or equal to the melting point of the light-shielding layer and controlling the heating duration to be a first preset duration so that the light-emitting element array is bonded and electrically connected to the first substrate and the light-shielding layer is melted and flows and extends to a side of the eutectic material block. In one or more embodiments, the melting point of the light-shielding layer herein is the melting point of the thermoplastic light-shielding material.

In this embodiment, during the process of laser bonding, the laser bonding temperature is controlled to be higher than or equal to the melting point of the light-shielding layer, and the duration at the laser bonding temperature is controlled to be a first preset duration. In this manner, the light-shielding layer is melted and flows, which helps the light-shielding layer fill a gap in the driving electrodes and facilitates contact with a eutectic material block. The first preset duration may be 1.5 times the conventional laser bonding duration.

The operation of laser bonding the light-emitting element array and the first substrate in the optional S330 includes the steps below.

The laser bonding temperature is controlled to be a first bonding temperature so that the light-emitting element array is bonded and electrically connected to the first substrate.

The laser bonding temperature is controlled to rise from the first bonding temperature to a second bonding temperature to enable the light-shielding layer to melt and flow.

The first bonding temperature is higher than or equal to the melting point of the eutectic material block, and the second bonding temperature is higher than or equal to the melting point of the light-shielding layer.

In this embodiment, during the process of laser bonding, the laser bonding temperature may first be controlled to be a first bonding temperature that may be equal to or greater than the melting point of the eutectic material block. In this manner, the eutectic material block is melted, thereby facilitating the bonding of the light-emitting element and the first substrate. Then, the temperature is controlled to rise to a second bonding temperature. The second bonding temperature may be equal to or greater than the melting point of the light-shielding layer. In this manner, the light-shielding layer is melted and flows, and the light-shielding layer is facilitated to fill a gap in the driving electrodes and contact a eutectic material block.

In one or more embodiments, the heating duration at the first bonding temperature is greater than or equal to the heating duration at the second bonding temperature. During the process of laser bonding, the first bonding temperature is used to melt the eutectic material block to bond the light-emitting element to the first substrate. To ensure the bonding yield, the heating duration at the first bonding temperature is slightly longer. During the process of laser bonding, the second bonding temperature is used to melt the light-shielding layer. When the high-temperature heating duration is slightly longer, the operation of the light-emitting element may be affected. Based on this, the heating time of the second bonding temperature is designed to be less than or equal to the heating time of the first bonding temperature.

As described above, by the control of parameters such as the thickness of the light-shielding layer, the first bonding temperature and heating time, and the second bonding temperature and heating time, the morphology of the light-shielding layer can be controlled so that the light-shielding layer fills a gap in the driving electrodes and is in contact with the sidewall of the eutectic material block.

In one or more embodiments, the operation of forming the light-shielding layer and the eutectic layer on the supporting substrate in S320 includes forming the eutectic layer on the supporting substrate, where the eutectic layer includes multiple eutectic material blocks; forming the light-shielding layer on the eutectic layer, where the light-shielding layer has multiple light-shielding openings. In one or more embodiments, forming the light-shielding layer on the eutectic layer includes attaching a light-shielding film to the eutectic layer; bonding and etching the light-shielding film to form the light-shielding layer having multiple light-shielding openings.

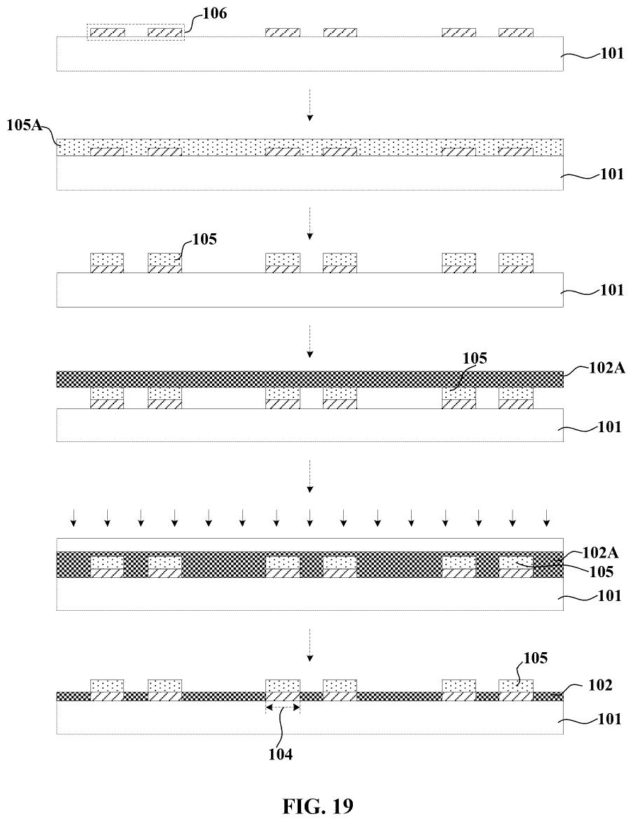

FIG. 19 is a flowchart illustrating the manufacturing of a first substrate according to an embodiment of the present disclosure. As shown in FIG. 19, the process of manufacturing the first substrate includes the steps below.
(1) A supporting substrate 101 is provided; the supporting substrate 101 includes a driving electrode unit 106, and the driving electrode unit 106 includes two driving electrodes.
(2) A eutectic layer 105A is formed on the supporting substrate 101.
(3) The eutectic layer 105A is patterned to form multiple eutectic material blocks 105.
(4) A light-shielding film 102A is attached to the eutectic layer.
(5) The light-shielding film 102A is bonded and etched to form a light-shielding layer 102 having multiple light-shielding openings 104.

In this embodiment, the light-shielding layer is formed by an etching process after film application, which is not limited by high PPI and is applicable to manufacturing a high-resolution display panel. The technique is simple.

In one or more embodiments, the operation of forming the light-shielding layer and the eutectic layer on the supporting substrate in S320 includes forming the eutectic layer on the supporting substrate, where the eutectic layer includes multiple eutectic material blocks; forming the light-shielding layer on the eutectic layer, where the light-shielding layer has multiple light-shielding openings. In one or more embodiments, forming the light-shielding layer on the eutectic layer includes coating a light-shielding material layer on the eutectic layer; exposing and developing the light-shielding material layer to form the light-shielding layer having the multiple light-shielding openings.

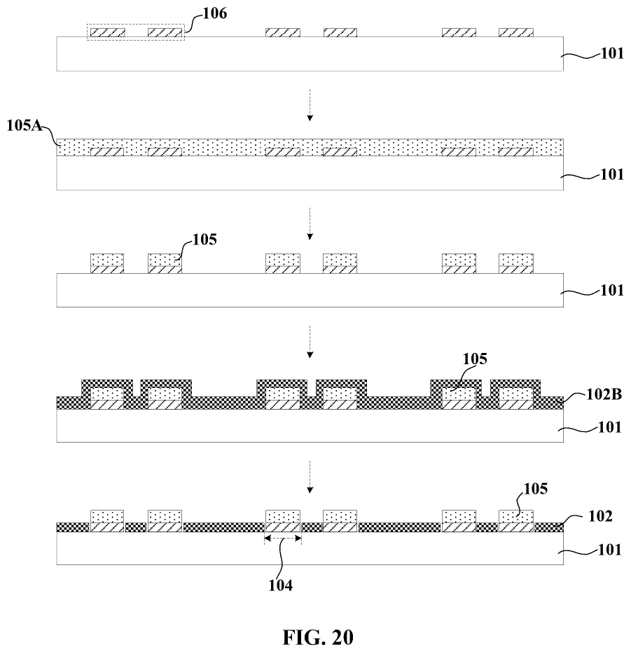

FIG. 20 is another flowchart illustrating the manufacturing of a first substrate according to an embodiment of the present disclosure. As shown in FIG. 20, the process of manufacturing the first substrate includes the steps below.
(1) A supporting substrate 101 is provided; the supporting substrate 101 includes a driving electrode unit 106, and the driving electrode unit 106 includes two driving electrodes.
(2) A eutectic layer 105A is formed on the supporting substrate 101.
(3) The eutectic layer 105A is patterned to form multiple eutectic material blocks 105.
(4) A light-shielding material layer 102B is coated on the eutectic layer.
(5) The light-shielding material layer 102B is exposed and developed to form a light-shielding layer 102 having multiple light-shielding openings 104.

In this embodiment, the light-shielding layer is formed using a photolithography process, which is not limited by high PPI and is applicable to manufacturing a high-resolution display panel. The technique is simple.

In one or more embodiments, the manufacturing method includes that at least two light-emitting element arrays are provided, where a light-emitting element array of the least two light-emitting element arrays includes multiple sub-pixels having the same color, and the multiple sub-pixels included in one of the at least two light-emitting element arrays have a color different from the multiple sub-pixels included in another one of the at least two light-emitting element arrays.

Laser bonding the light-emitting element array and the first substrate includes laser bonding and heating each sub-pixel in one of the at least two light-emitting element arrays and the first substrate using a point light source heating method, where a sub-pixel includes a light-emitting element.

In one or more embodiments, sub-pixels in the same light-emitting element array have the same color, and sub-pixels in different light-emitting element arrays have different colors. When the display panel includes at least two kinds of sub-pixels of different colors, different light-emitting element arrays need to be sequentially transferred and bonded through at least two transfer processes in the manufacturing process of the display panel to achieve the transfer and bonding of sub-pixels of different colors.

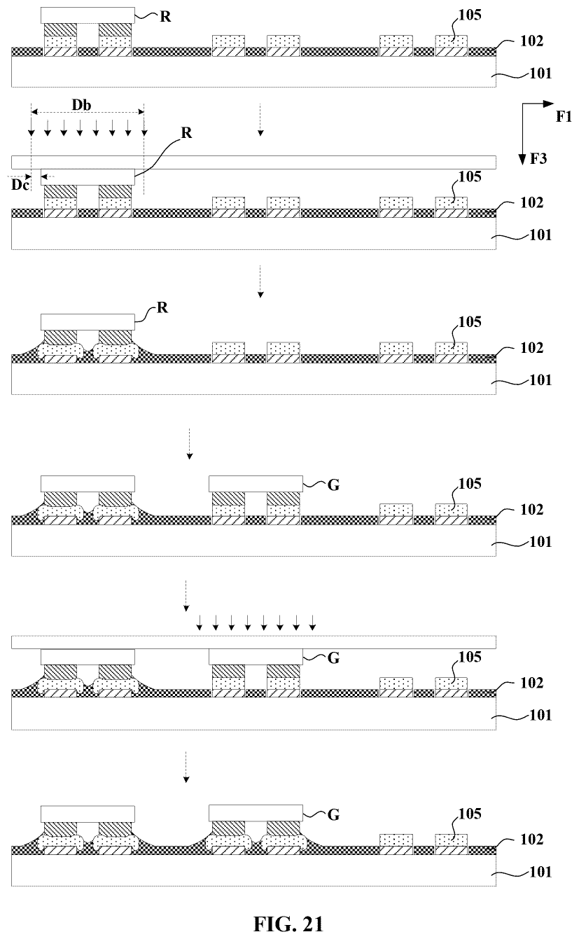

FIG. 21 is a flowchart illustrating laser bonding according to an embodiment of the present disclosure. As shown in FIG. 21, in one or more embodiments, two light-emitting element arrays are provided. One light-emitting element array includes red sub-pixels R, and the other light-emitting element array includes green sub-pixels G. The process of manufacturing the display panel includes the steps described below.
(1) The light-emitting element array in which the red sub-pixels R are located is transferred above the supporting substrate 101, where the red sub-pixels R are transferred and placed at the target position.
(2) The light-emitting element array and the first substrate 100 are laser bonded, where the red sub-pixels R and the first substrate 100 are laser bonded and heated using a point light source heating method, and the light-shielding layer 102 at a position corresponding to the red sub-pixels R is melted and flows.
(3) This bonding is completed. After cooling, the light-shielding layer 102 at the position corresponding to the red sub-pixels R overlaps the eutectic material block 105 in the direction perpendicular to the supporting substrate 101.
(4) The light-emitting element array in which the green sub-pixels G are located is transferred and bonded. For the process, reference is made to the preceding (1) to (3).

In one or more embodiments, in the point light source heating method, the diameter of a laser spot projected by a point light source onto a sub-pixel is greater than or equal to the size of the sub-pixel. The light-emitting element array is transferred and bonded. During the process of laser bonding, the diameter of a laser spot projected by the laser onto the corresponding sub-pixel should be greater than or equal to the size of this sub-pixel.

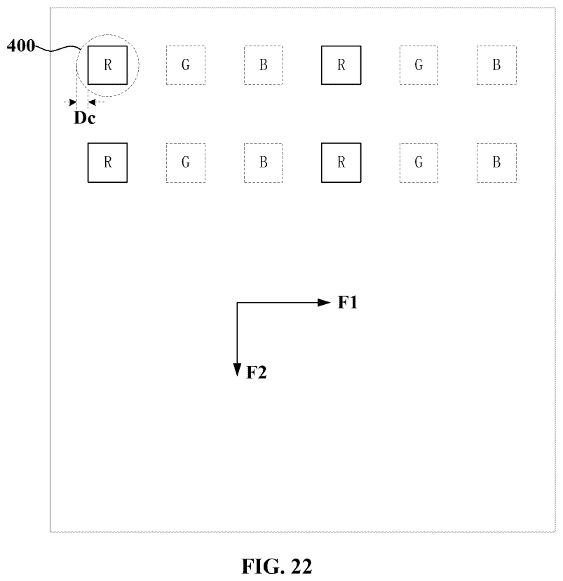

FIG. 22 is a schematic diagram illustrating laser bonding according to an embodiment of the present disclosure. As shown in FIG. 22, the red sub-pixel R is used as an example. During the process of laser bonding, the laser spot 400 projected by the laser onto the red sub-pixel R should be circular. As shown in FIG. 21 and FIG. 22, the diameter Db of the laser spot 400 is greater than or equal to the maximum length of the red sub-pixels R in the first direction F1, and the diameter of the laser spot 400 is greater than or equal to the maximum length of the red sub-pixel R in the second direction F2. Based on this, the laser spot 400 covers the red sub-pixel R in the third direction F3, and the laser bonding of the red sub-pixel R can be completed.

In one or more embodiments, In the point light source heating method, the distance between the edge of the laser spot projected by the point light source onto the sub-pixel and the light-emitting edge of the sub-pixel is less than or equal to 6 microns. When the diameter of the laser spot is too large, the laser spot covers the corresponding sub-pixel and may also at least partially cover adjacent sub-pixels, causing the eutectic material blocks of the adjacent sub-pixels to melt. It should be noted that in this embodiment, the sub-pixel may be a micro light-emitting diode-based sub-pixel. In this manner, the light-emitting edge of the sub-pixel is the light-emitting edge of the micro light-emitting diode.

As shown in FIG. 21 and FIG. 22, the distance Dc between the edge of the laser spot 400 and the light-emitting edge of the red sub-pixel R is less than or equal to 6 microns. It can be understood that for a low-resolution display panel, the distance between adjacent sub-pixels is relatively large, and the distance between the edge of the laser spot and the light-emitting edge of the corresponding sub-pixel may be appropriately adjusted and increased. For a high-resolution display panel, the distance between adjacent sub-pixels is relatively small, and the distance between the edge of the laser spot and the light-emitting edge of the corresponding sub-pixel may be appropriately adjusted and reduced. In one or more embodiments, in the point light source heating method, the distance between the edge of the laser spot projected by the point light source onto the sub-pixel and the light-emitting edge of the sub-pixel is less than or equal to 3 microns.

In one or more embodiments, the light-emitting element array includes a first sub-pixel and a second sub-pixel, and the first sub-pixel and the second sub-pixel are configured of different colors. In one or more embodiments, the light-emitting element array also includes a third sub-pixel, and the color of the third sub-pixel is different from the color of the first sub-pixel or the color of the second sub-pixel. In one or more embodiments, the first sub-pixel, the second sub-pixel, and the third sub-pixel are configured to be red, green, and blue, respectively. Illustratively, the first sub-pixel is configured to be red, the second sub-pixel is configured to be green, and the third sub-pixel is configured to be blue.

In one or more embodiments, the light-emitting element array includes sub-pixels of different colors. Generally, the light-emitting element array includes all the sub-pixels required by the display panel. In this case, during the process of manufacturing the display panel, the light-emitting element array is transferred and bonded through a one-time transfer process to achieve the transfer and bonding of sub-pixels of different colors.

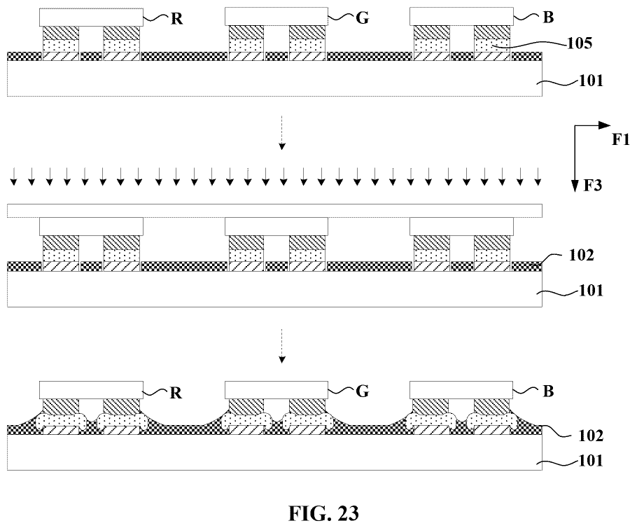

FIG. 23 is another flowchart illustrating the laser bonding according to an embodiment of the present disclosure. As shown in FIG. 23, in one or more embodiments, a light-emitting element array is provided, and the light-emitting element array includes a red sub-pixel R, a green sub-pixel G, and a blue sub-pixel B. The process of manufacturing the display panel includes the steps described below.
(1) The light-emitting element array is transferred above the supporting substrate 101, where the red sub-pixel R, the green sub-pixel G, and the blue sub-pixel B are correspondingly placed at the target positions.
(2) The light-emitting element array and the first substrate 100 are laser bonded, where the front display panel is laser bonded and heated using a surface light source heating method, and the light-shielding layer 102 at a position corresponding a sub-pixel is melted and flows.
(3) The bonding is completed. After cooling, the light-shielding layer 102 at the position corresponding to the sub-pixel overlaps the eutectic material block 105 in the direction perpendicular to the supporting substrate 101.

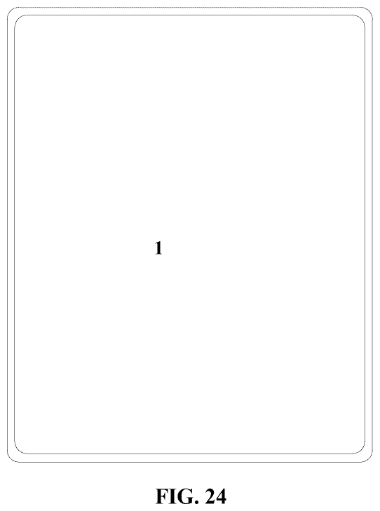

Embodiments of the present disclosure also provide a display device. The display device includes the display panel provided in any of the preceding embodiments. FIG. 24 is a schematic diagram of a display device according to an embodiment of the present disclosure. As shown in FIG. 24, the display device 1 includes but is not limited to a mobile phone, a tablet, a computer, and a digital camera. Furthermore, the display device 1 may be but is not limited to an LED display device, a micro LED display device, and a flexible display device.

It is to be understood that various forms of processes shown above may be adopted with steps reordered, added, or deleted. For example, the steps described in the present disclosure may be performed in parallel, sequentially, or in different orders, as long as the desired results of the technical solutions of the present disclosure can be achieved, and no limitation is imposed herein.

What is claimed is:

1. A display panel, comprising:
a first substrate, wherein the first substrate comprises a supporting substrate, a light-shielding layer disposed on the supporting substrate, and a eutectic layer disposed on the supporting substrate, wherein the light-shielding layer has a plurality of light-shielding openings, the eutectic layer comprises a plurality of eutectic material blocks corresponding to the plurality of light-shielding openings, respectively, and in a direction perpendicular to the first substrate, at least one of the plurality of eutectic material blocks overlaps a corresponding light-shielding opening of the plurality of light-shielding openings; and
a light-emitting element array, wherein the light-emitting element array comprises a plurality of light-emitting elements, wherein the light-emitting element array is electrically connected to the first substrate.

2. The display panel of claim 1, wherein the light-shielding layer comprises a thermoplastic light-shielding material; and
wherein the light-emitting element array is bonded and electrically connected to the first substrate, and a temperature at which the light-emitting element array and the first substrate are bonded is higher than or equal to a melting point of the light-shielding material; or, a melting point of the light-shielding material is higher than or equal to a melting point of at least one of the plurality of eutectic material blocks.

3. The display panel of claim 1, wherein the light-shielding layer is in contact with a side surface of at least one of the plurality of eutectic material blocks.

4. The display panel of claim 3, wherein the light-shielding layer disposed between two adjacent eutectic material blocks of the plurality of eutectic material blocks comprises a first block and a second block, and the first block is disposed on a side of the second block away from the two adjacent eutectic material blocks; and
Ha≤Hb;
wherein in the direction perpendicular to the first substrate, Ha denotes a thickness of the first block, and Hb denotes a thickness of a side of the second block away from the two adjacent eutectic material blocks.

5. The display panel of claim 4, wherein 2×Ha≤Hm; and
in the direction perpendicular to the first substrate, Hm is a thickness of a side of the second block facing to the two adjacent eutectic material blocks.

6. The display panel of claim 4, wherein a side of the second block away from the supporting substrate is an arc-shaped edge, and the arc-shaped edge is convex toward the two adjacent eutectic material blocks, or, wherein a side of the first block away from the supporting substrate is a straight edge.

7. The display panel of claim 1, wherein in the direction perpendicular to the first substrate, at least one of the plurality of eutectic material blocks covers the corresponding light-shielding opening.

8. The display panel of claim 1, wherein the supporting substrate comprises a plurality of driving electrode units, at least one of the plurality of driving electrode units comprises a first driving electrode and a second driving electrode, and at least one of the plurality of light-emitting elements comprises a first light-emitting electrode and a second light-emitting electrode;
a light-emitting element of the plurality of light-emitting elements is electrically connected to a driving electrode unit of the plurality of driving electrode units, the first light-emitting electrode is bonded and electrically connected to the first driving electrode through one of the plurality of eutectic material blocks, and the second light-emitting electrode is bonded and electrically connected to the second driving electrode through another one of the plurality of eutectic material blocks; and
at least one of the plurality of eutectic material blocks comprises a first bonding part and a second bonding part, and in the direction perpendicular to the first substrate, the first bonding part overlaps one of the first light-emitting electrode and the second light-emitting electrode in at least one of the plurality of light-emitting elements or the first bonding part overlaps one of the first driving electrode and the second driving electrode in at least one of the plurality of driving electrode units, and the second bonding part overlaps none of the first light-emitting electrode or the second light-emitting electrode in at least one of the plurality of light-emitting elements or the second bonding part overlaps none of the first driving electrode or the second driving electrode in at least one of the plurality of driving electrode units.

9. The display panel of claim 8, wherein the second bonding part is provided with a protrusion facing to the supporting substrate; and
wherein in the direction perpendicular to the first substrate, the protrusion surrounds the first bonding part, or, wherein in a direction parallel to the first substrate, a gap exists between the protrusion and the first driving electrode or the second driving electrode in a driving electrode unit of the plurality of driving electrode units.

10. The display panel of claim 8, wherein the light-shielding layer comprises a first extension part and a second extension part;
the first extension part extends to a side of a eutectic material block of the plurality of eutectic material blocks away from a light-emitting element of the plurality of light-emitting elements and is in contact with a side of a driving electrode in a driving electrode unit of the plurality of driving electrode units; and
the second extension part extends along a side of the eutectic material block and is in contact with the first extension part.

11. The display panel of claim 10, wherein the first extension part is filled in a gap between the eutectic material block and the driving electrode in the driving electrode unit.

12. The display panel of claim 10, wherein the light-shielding layer further comprises a third extension part; and
the third extension part extends to a side of a eutectic material block of the plurality of eutectic material blocks away from a driving electrode unit of the plurality of driving electrode units, the third extension part is in contact with a side of a light-emitting electrode in a light-emitting element of the plurality of light-emitting elements, and the third extension part is in contact with the second extension part.

13. The display panel of claim 12, wherein the first extension part, the second extension part, and the third extension part of the light-shielding layer are all in contact with the second bonding part of the eutectic material block.

14. The display panel of claim 8, wherein in the direction perpendicular to the first substrate, the light-shielding layer covers a second bonding part of a eutectic material block of the plurality of eutectic material blocks.

15. A manufacturing method for a display panel, comprising:
providing a first substrate and a light-emitting element array, wherein the first substrate comprises a supporting substrate;
forming a light-shielding layer and a eutectic layer on the supporting substrate, wherein the light-shielding layer has a plurality of light-shielding openings, the eutectic layer comprises a plurality of eutectic material blocks corresponding to the plurality of light-shielding openings, respectively, and in a direction perpendicular to the first substrate, a eutectic material block of the plurality of eutectic material blocks overlaps a corresponding light-shielding opening; and
laser bonding the light-emitting element array and the first substrate.

16. The manufacturing method of claim 15, wherein the light-shielding layer comprises a thermoplastic light-shielding material.

17. The manufacturing method of claim 15, wherein laser bonding the light-emitting element array and the first substrate comprises:
controlling a laser bonding temperature to be higher than or equal to a melting point of the light-shielding layer to enable the light-emitting element array to be bonded and electrically connected to the first substrate and to enable the light-shielding layer to melt and flow;
or,
wherein laser bonding the light-emitting element array and the first substrate comprises:
controlling a laser bonding temperature to be higher than or equal to a melting point of the light-shielding layer and controlling heating duration to be a first preset duration to enable the light-emitting element array to be bonded and electrically connected to the first substrate and to enable the light-shielding layer to melt and flow and to extend to a side of at least one of the plurality of eutectic material blocks;
or,
wherein laser bonding the light-emitting element array and the first substrate comprises:
controlling a laser bonding temperature to be a first bonding temperature to enable the light-emitting element array to be bonded and electrically connected to the first substrate; and
controlling the laser bonding temperature to rise from the first bonding temperature to a second bonding temperature to enable the light-shielding layer to melt and flow;
wherein the first bonding temperature is higher than or equal to a melting point of at least one of the plurality of eutectic material blocks, and the second bonding temperature is higher than or equal to a melting point of the light-shielding layer; and wherein heating duration at the first bonding temperature is greater than or equal to heating duration at the second bonding temperature.

18. The manufacturing method of claim 15, wherein forming the light-shielding layer and the eutectic layer on the supporting substrate comprises:
forming the eutectic layer on the supporting substrate, wherein the eutectic layer comprises the plurality of eutectic material blocks; and
forming the light-shielding layer on the eutectic layer, wherein the light-shielding layer has the plurality of light-shielding openings; and
wherein forming the light-shielding layer on the eutectic layer comprises: attaching a light-shielding film to the eutectic layer; and bonding and etching the light-shielding film to form the light-shielding layer having the plurality of light-shielding openings; or, wherein forming the light-shielding layer on the eutectic layer comprises: coating a light-shielding material layer on the eutectic layer; and exposing and developing the light-shielding material layer to form the light-shielding layer having the plurality of light-shielding openings.

19. The manufacturing method of claim 15, comprising: providing at least two light-emitting element arrays, wherein a light-emitting element array of the least two light-emitting element arrays comprises a plurality of sub-pixels having a same color, and the plurality of sub-pixels comprised in one of the at least two light-emitting element arrays have a color different from the plurality of sub-pixels comprised in another one of the at least two light-emitting element arrays; and
laser bonding the light-emitting element array and the first substrate comprising: laser bonding and heating at least one of the plurality of sub-pixels in one of the at least two light-emitting element arrays and the first substrate using a point light source heating method;
wherein each of the plurality of sub-pixels comprises a light-emitting element; and
wherein in the point light source heating method, a diameter of a laser spot projected by a point light source onto a sub-pixel of the plurality of sub-pixels is greater than or equal to a size of the sub-pixel.

20. A display device, comprising a display panel, wherein the display panel comprises:
a first substrate, wherein the first substrate comprises a supporting substrate, a light-shielding layer disposed on the supporting substrate, and a eutectic layer disposed on the supporting substrate, wherein the light-shielding layer has a plurality of light-shielding openings, the eutectic layer comprises a plurality of eutectic material blocks corresponding to the plurality of light-shielding openings, respectively, and in a direction perpendicular to the first substrate, at least one of the plurality of eutectic material blocks overlaps a corresponding light-shielding opening of the plurality of light-shielding openings; and
a light-emitting element array, wherein the light-emitting element array comprises a plurality of light-emitting elements, wherein the light-emitting element array is electrically connected to the first substrate.
